(19) United States
(12) Patent Application Publication
(10) Pub. No.: US 2018/0212132 A1
(43) Pub. Date: Jul. 26, 2018

(54) THERMOELECTRIC ELEMENT AND COOLING APPARATUS COMPRISING SAME

(71) Applicant: LG INNOTEK CO., LTD., Seoul (KR)

(72) Inventors: Sang In YOON, Seoul (KR); Sung Chul KIM, Seoul (KR); Myoung Lae ROH, Seoul (KR)

(21) Appl. No.: 15/746,093

(22) PCT Filed: Jul. 20, 2016
(86) PCT No.: PCT/KR2016/007927

§ 371 Date: Jan. 19, 2018

(30) Foreign Application Priority Data
Jul. 20, 2015 (KR) 10-2015-0102563

(51) Int. Cl. H01L 35/32; H01L 35/16

(52) U.S. Cl. CPC H01L 35/32; H01L 35/34; H01L 35/16

(57) ABSTRACT

The thermoelement according to one embodiment of the present invention includes: a first substrate; multiple p-type thermoelectric legs and multiple n-type thermoelectric legs, which are alternately disposed on the first substrate; a second substrate disposed on the multiple p-type thermoelectric legs and the multiple n-type thermoelectric legs; and multiple electrodes for serially connecting the multiple p-type thermoelectric legs and the multiple n-type thermoelectric legs, wherein the peak number of the n-type thermoelectric legs and that of the p-type thermoelectric legs differ in X-ray diffraction (XRD) analysis in the range of 2θ=20-60°.

### TECHNICAL FIELD

The present invention relates to a thermoelectric element, and more specifically, to a thermoelectric element and a cooling apparatus including the same.

### BACKGROUND ART

A thermo-electric effect, which is an effect generated by movement of electrons and holes in a material, means direct energy conversion between heat and electricity.

The thermoelectric effect is a general term for an element using the thermo-electric effect and includes an element using a temperature change of electric resistance, an element using a Seeback effect which is a phenomenon in which an electromotive force is generated by a temperature difference, and an element using a Peltier effect which is a phenomenon in which heat absorption or heat emission is generated by a current.

The thermoelectric effect has been variously applied to home appliances, electronic components, communication components, and the like, and demand for the thermoelectric performance of the thermoelectric element has been gradually increasing.

The thermoelectric element includes a substrate, an electrode, and a thermoelectric leg. The thermoelectric leg may be an important index influencing the performance of the thermoelectric element. When the thermoelectric element is an element using the Peltier effect, holes of a P-type thermoelectric leg and an electron of an N-type thermoelectric leg are moved when a voltage is applied to the thermoelectric element from the outside, and heat absorption and heat emission are caused.

In this case, the P-type thermoelectric leg and the N-type thermoelectric leg have different electrical conductivities due to a thermoelectric material difference therebetween, and thus the performance is limited.

### Technical Problem

The present invention is directed to providing a thermoelectric element with improved performance and a cooling apparatus including the same.

### Technical Solution

One aspect of the present invention provides a thermoelectric element which includes a first substrate, a plurality of P-type thermoelectric legs and a plurality of N-type thermoelectric legs alternately disposed on the first substrate, a second substrate disposed on the plurality of P-type thermoelectric legs and the plurality of N-type thermoelectric legs, and a plurality of electrodes configured to connect the plurality of P-type thermoelectric legs with the plurality of N-type thermoelectric legs in series, wherein the number of peaks of the N-type thermoelectric legs and the number of peaks of the P-type thermoelectric legs are different in an X-ray diffraction (XRD) analysis within a range of 2θ=20 to 60°.

The number of efficient peaks of the N-type thermoelectric legs may be less than the number of efficient peaks of the P-type thermoelectric legs, and the efficient peaks may account for 4% or more of 100% total peak intensity.

A difference between the number of efficient peaks of the N-type thermoelectric legs and the number of efficient peaks of the P-type thermoelectric legs may be 6 or more.

A highest peak intensity of the effective peaks of the N-type thermoelectric legs may be greater than a highest peak intensity of the effective peaks of the P-type thermoelectric legs.

A difference between the highest peak intensity of the efficient peaks of the N-type thermoelectric legs and the highest peak intensity of the efficient peaks of the P-type thermoelectric legs is 50% or more.

A highest peak of the efficient peaks of the N-type thermoelectric legs may be shown on a (0, 0, X) surface, wherein X may be a random number.

A highest peak intensity of the efficient peaks of the N-type thermoelectric legs may be 90% or more of 100% total intensity.

The N-type thermoelectric legs and the P-type thermoelectric legs may include bismuth-telluride (Bi—Te).

The N-type thermoelectric legs may have the highest peak on a (0, 0, 15) surface, and the P-type thermoelectric legs may have the highest peak on a (0, 1, 5) surface.

The N-type thermoelectric legs may have more uniform crystal orientations than crystal orientations of the P-type thermoelectric legs.

The N-type thermoelectric leg may have a heat conductivity greater than the heat conductivity of the P-type thermoelectric leg.

The N-type thermoelectric legs may be manufactured through a zone-melting method, and the P-type thermoelectric legs may be manufactured through a powder sintering method.

Another aspect of the present invention provides a cooling apparatus comprising a thermoelectric element which includes a first substrate, a plurality of P-type thermoelectric legs and a plurality of N-type thermoelectric legs alternately disposed on the first substrate, a second substrate disposed on the plurality of P-type thermoelectric legs and the plurality of N-type thermoelectric legs, and a plurality of electrodes configured to connect the plurality of P-type thermoelectric legs with the plurality of N-type thermoelectric legs in series, wherein the number of peaks of the N-type thermoelectric legs and the number of peaks of the P-type thermoelectric legs are different from each other in an XRD analysis within a range of 2θ=20 to 60°.

### Advantageous Effects

According to an embodiment of the present invention, a thermoelectric element with excellent performance can be obtained. Particularly, a thermoelectric element with a high Seebeck coefficient (ZT) can be obtained by maximizing heat conductivities and electric conductivities of the P-type thermoelectric leg and the N-type thermoelectric leg thereof. Therefore, a cooling apparatus with excellent cooling performance can be obtained.

### DESCRIPTION OF DRAWINGS

FIG. 1 is a cross-sectional view of a thermoelectric element.

FIG. 2 is a perspective view of the thermoelectric element.

FIG. 3 is a scanning electron microscope (SEM) photo of an N-type thermoelectric leg manufactured through a zone-melting method.

FIG. 4 is an SEM photo of a P-type thermoelectric leg manufactured through a zone-melting method.

FIG. 5 is an SEM photo of an N-type thermoelectric leg manufactured through a powder sintering method.

FIG. 6 is an SEM photo of a P-type thermoelectric leg manufactured through a powder sintering method.

FIG. 7 is a cross-sectional view of a thermoelectric element according to an embodiment of the present invention.

FIG. 8 is a perspective view of the thermoelectric element according to the embodiment of the present invention.

FIG. 9 shows an X-ray diffraction (XRD) analysis result of an N-type thermoelectric leg according to the embodiment of the present invention.

FIG. 10 shows an XRD analysis result of a P-type thermoelectric leg according to the embodiment of the present invention.

### MODES OF THE INVENTION

While the invention is susceptible to various modifications and alternative forms, specific embodiments thereof will be shown by way of example in the drawings and described in detail therein. It should be understood, however, that there is no intent to limit the invention to the particular forms disclosed, but on the contrary, the invention is to cover all modifications, equivalents, and alternatives falling within the spirit and scope of the invention.

It should be understood that, although the terms “first,” “second,” etc. may be used herein to describe various elements, these elements are not limited by the terms. The terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It should be understood that when an element is referred to as being “connected” or “coupled” to another element, the element can be directly connected or coupled to the other element or an intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of describing particular embodiments only and is not intended to limit the invention. As used herein, the singular forms “a,” “an”, and “the” are intended to include the plural forms as well, unless the context clearly indicates otherwise. It should be further understood that the terms “comprise,” “comprising,” “include” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It should be further understood that terms, such as those defined in commonly used dictionaries, should be interpreted as having a meaning that is consistent with their meaning in the context of the relevant art and are not to be interpreted in an idealized or overly formal sense unless expressly so defined herein.

Hereinafter, preferred embodiments of the present invention will be described in detail with reference to the accompanying drawings, but the same or similar elements are designated with the same numeral references regardless of the numerals in the drawings, and redundant description thereof will be omitted.

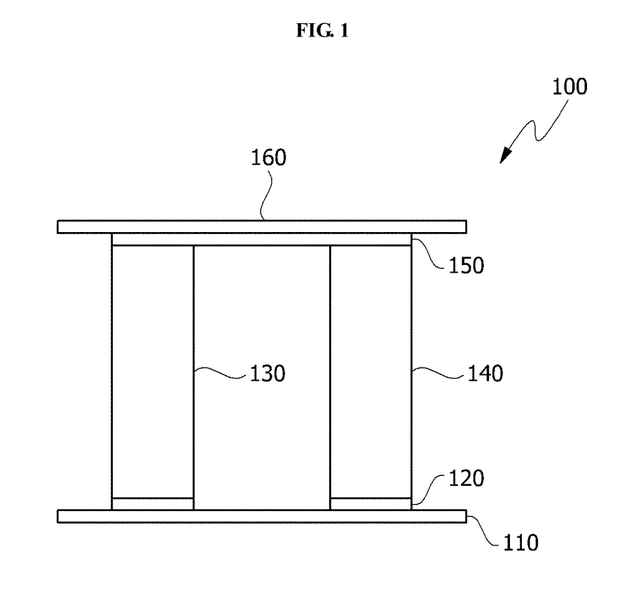

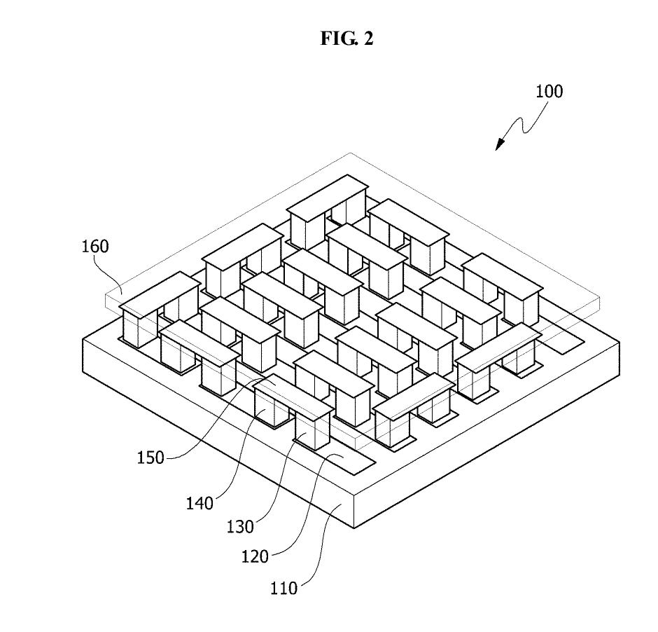

FIG. 1 is a cross-sectional view of a thermoelectric element, and FIG. 2 is a perspective view of the thermoelectric element.

Referring to FIGS. 1 and 2, a thermoelectric element 100 includes a lower substrate 110, a lower electrode 120, a P-type thermoelectric leg 130, an N-type thermoelectric leg 140, an upper electrode 150, and an upper substrate 160.

The lower electrode 120 is disposed between the lower substrate 110 and lower surfaces of the P-type thermoelectric leg 130 and the N-type thermoelectric leg 140, and the upper electrode 150 is disposed between the upper substrate 160 and upper surfaces of the P-type thermoelectric leg 130 and the N-type thermoelectric leg 140. Thus, a plurality of P-type thermoelectric legs 130 and a plurality of N-type thermoelectric leg 140 are electrically connected by the lower electrode 120 and the upper electrode 150.

For example, due to the Peltier effect, when a direct current (DC) voltage is applied to the lower electrode 120 and the upper electrode 150 through lead lines, a substrate in which a current flows from the P-type thermoelectric leg 130 to the N-type thermoelectric leg 140 absorbs heat and acts as a cooling unit, and a substrate in which the current flows from the N-type thermoelectric leg 140 to the P-type thermoelectric leg 130 is heated and acts as a heat emission unit.

Here, the P-type thermoelectric leg 130 and the N-type thermoelectric leg 140 may be a bismuth-telluride (Bi—Te)-based thermoelectric leg including bismuth (Bi) and tellurium (Ti) as main materials.

The performance of the thermoelectric element according to the embodiment of the present invention may be shown with a Seeback index. A Seeback index (ZT) may be shown with Equation 1.

ZT=α^{t}σT/k [Equation 1]

Here, α denotes a Seeback coefficient [V/K], a denotes an electrical conductivity [S/m], and α2σ denotes a power factor [W/mK²]. Further, T denotes a temperature, and k denotes a heat conductivity [W/mK]. k may be expressed as acₚρ, a denotes thermal diffusivity [cm²/S], cₚ denotes specific heat [J/gK], and ρ denotes density [g/cm³].

To obtain the Seeback index of the thermoelectric element, a Z value (V/K) is measured with a Z meter, and the Seeback index (ZT) may be calculated with the measured Z value. The thermoelectric leg may influence the Seeback index of the thermoelectric element.

Meanwhile, the thermoelectric leg may be manufactured according to a zone melting method or a powder sintering method. According to the zone melting method, a thermoelectric leg is obtained through a method in which an ingot of a thermoelectric material is manufactured, and heat is slowly applied to the ingot to refine the ingot such that particles are re-arranged in a single direction and then slowly cooled. According to the powder sintering method, a thermoelectric leg is obtained through a process in which an ingot of a thermoelectric material is manufactured and is crushed and sifted such that powder for the thermoelectric leg are obtained, and then the powder is sintered.

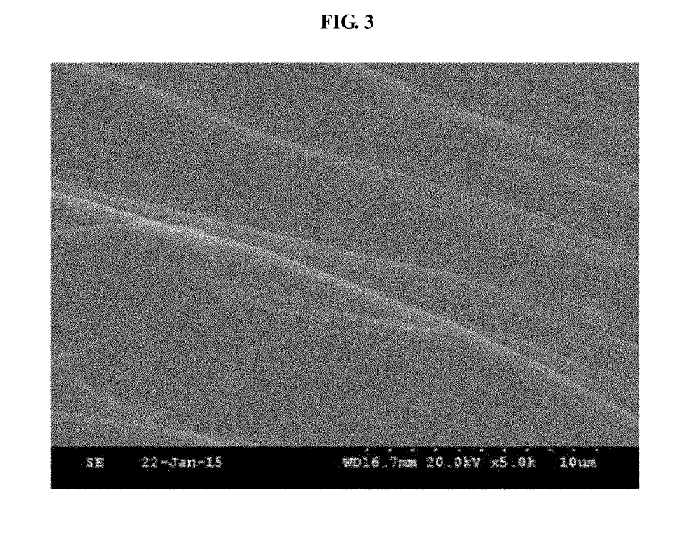

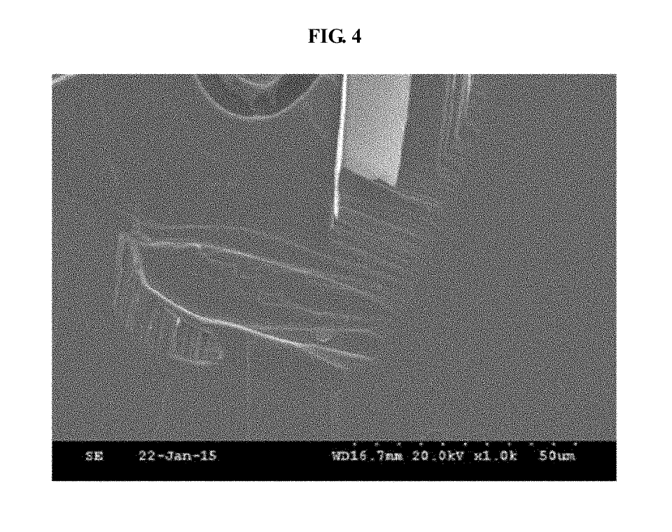

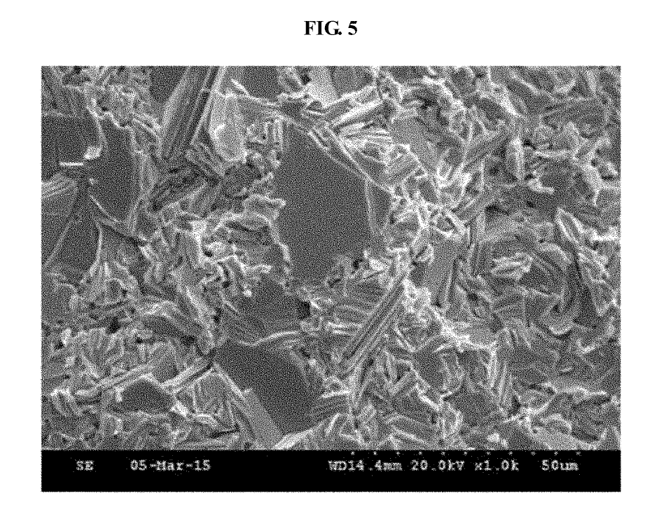

FIG. 3 is a scanning electron microscope (SEM) photo of an N-type thermoelectric leg manufactured through the zone-melting method, FIG. 4 is an SEM photo of a P-type thermoelectric leg manufactured through a zone-melting method, FIG. 5 is an SEM photo of an N-type thermoelectric leg manufactured through the powder sintering method, and FIG. 6 is an SEM photo of a P-type thermoelectric leg manufactured through a powder sintering method.

Table 1 shows characteristics of the thermoelectric leg manufactured according to the zone melting method and the thermoelectric leg manufactured through the powder sintering method.

TABLE 1

| | Zone melting method | | Powder sintering method | |
|---|---|---|---|---|
| | N-type | P-type | N-type | P-type |
| | thermoelectric leg | thermoelectric leg | thermoelectric leg | thermoelectric leg |
| Electrical conductivity | 100,000 to 110,000 | 80,000 to 90,000 | 70,000 to 80,000 | 90,000 to 100,000 |
| (S/m) | | | | |
| Seeback coefficient | 200 ± 10 | 210 ±10 | 210 ±10 | 200 ± 10 |
| (uV/K) | | | | |
| Heat conductivity | 1.2 to 1.6 | 1.2 to 1.6 | 0.9 to 1.1 | 0.9 to 1.1 |
| (W/mK) | | | | |

Referring to FIGS. 3 to 6 and Table 1, a crystal orientation of the thermoelectric leg manufactured according to the zone melting and a crystal orientation of the thermoelectric leg manufactured according to the powder sintering method are different. That is, the crystal orientation of the thermoelectric leg manufactured according to the zone melting is more uniform than the crystal orientation of the thermoelectric leg manufactured according to the powder sintering method. When the thermoelectric leg is manufactured according to the zone melting method, the orientation of a single crystal formed in a uniform direction may be obtained. When a thermoelectric leg is manufactured according to the powder sintering method, the orientation of a polycrystal formed in various directions may be obtained.

Meanwhile, when a thermoelectric leg is manufactured through the zone melting method, there are problems in that strength of thermoelectric leg is low due to low bonding strength between Bi and Te and it is hard to obtain a high Seeback index (ZT) due to high heat conductivity. Further, when a thermoelectric leg is manufactured through the powder sintering method, the thermoelectric leg may have high strength and low heat conductivity, but an N-type thermoelectric leg has very low electrical conductivity due to the performance of the thermoelectric material, and thus there is a problem in that it is hard to obtain a high Seeback index (ZT). Conversely, a P-type thermoelectric leg has high electrical conductivity even when manufactured through the powder sintering method, and a P-type thermoelectric leg manufactured through the powder sintering method may obtain high cooling performance.

Thus, in the embodiment of the present invention, the P-type thermoelectric leg and the N-type thermoelectric leg included in the thermoelectric element are manufactured through different methods, and thus electrical conductivity and the heat conductivity are optimized.

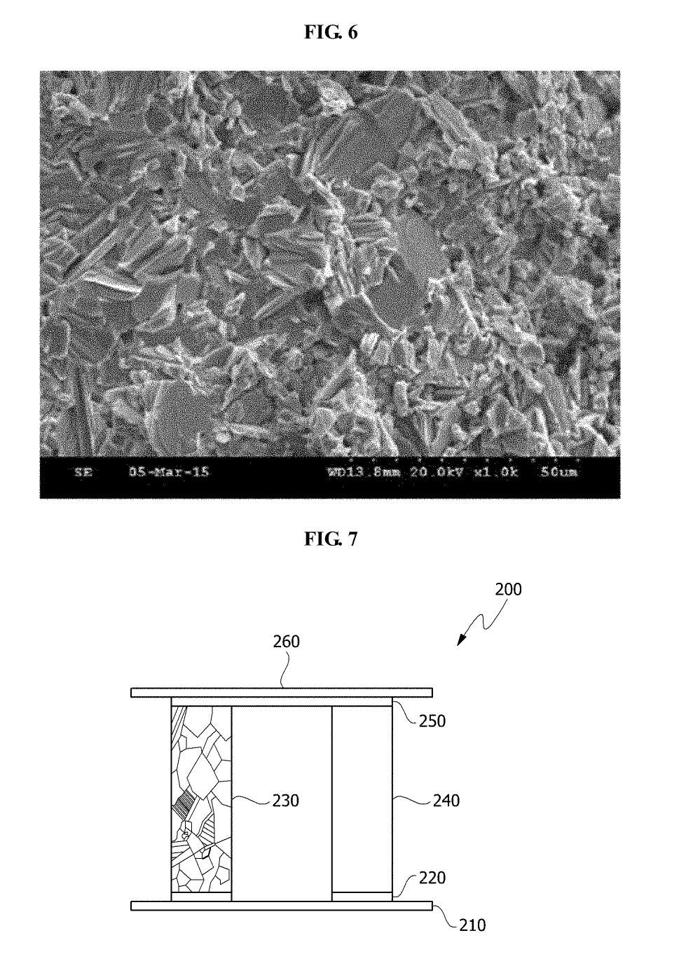

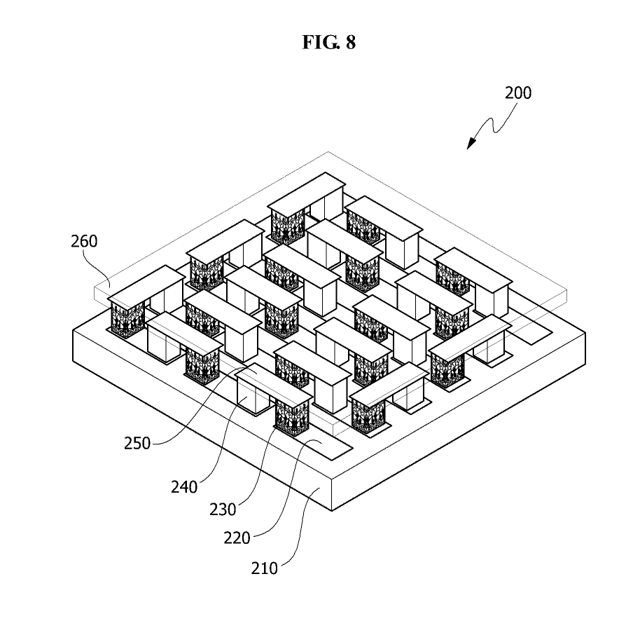

FIG. 7 is a cross-sectional view of a thermoelectric element according to an embodiment of the present invention, and FIG. 8 is a perspective view of the thermoelectric element according to the embodiment of the present invention.

Referring to FIGS. 7 and 8, a thermoelectric element 200 includes a lower substrate 210, a lower electrode 220, a P-type thermoelectric leg 230, an N-type thermoelectric leg 240, an upper electrode 250, and an upper substrate 260.

The lower electrode 220 is disposed between a lower substrate 210 and lower surfaces of the P-type thermoelectric leg 230 and the N-type thermoelectric leg 240, and the upper electrode 250 is disposed between the upper substrate 260 and the upper surfaces of the P-type thermoelectric leg 230 and the N-type thermoelectric leg 240. Thus, a plurality of P-type thermoelectric legs 230 and a plurality of N-type thermoelectric leg 240 are alternately disposed and are electrically connected by the lower electrode 220 and the upper electrode 250.

For example, due to the Peltier effect, when a DC voltage is applied to the lower electrode 220 and the upper electrode 250 through lead lines, a substrate in which a current flows from the P-type thermoelectric leg 230 to the N-type thermoelectric leg 240 absorbs heat to act as an cooling unit, and a substrate in which a current flows from the N-type thermoelectric leg 240 to the P-type thermoelectric leg 230 is heated and acts as a heat emission unit.

To this end, the lower substrate 210 and the upper substrate 260 may be a metal substrate such as a Cu substrate, a Cu alloy substrate, a Cu—Al alloy substrate, an Al₂O₃ substrate, or the like. Further, the lower electrode 220 and the upper electrode 250 may include an electrode material such as Cu, Ag, Ni, or the like, and thicknesses of lower electrode 220 and upper electrode 250 may be within a range of 0.01 to 0.3 mm. Although not shown, dielectric layers may be formed between the lower substrate 210 and the lower electrode 220 and between the upper substrate 260 and the upper electrode 250.

In this case, the P-type thermoelectric leg 230 and the N-type thermoelectric leg 240 may be a bismuth-telluride (Bi—Te)-based thermoelectric leg including bismuth (Bi) and tellurium (Ti) as main materials. For example, the P-type thermoelectric leg 230 may further include at least one among antimony (Sb), nickel (Ni), aluminum (Al), copper (Cu), silver (Ag), lead (Pb), boron (B), gallium (Ga), and indium (In). The N-type thermoelectric leg 240 may further include at least one among selenium (Se), nickel (Ni), aluminum (Al), copper (Cu), silver (Ag), lead (Pb), boron (B), gallium (Ga), and indium (In).

In this case, a crystal orientation of the P-type thermoelectric leg 230 is different from a crystal orientation of the N-type thermoelectric leg 240. That is, the N-type thermoelectric leg 240 has the crystal orientation shown in FIG. 3, and the P-type thermoelectric leg 230 has the crystal orientation shown in FIG. 6. As such, the crystal orientation of the N-type thermoelectric leg 240 is more uniform than the crystal orientation of the P-type thermoelectric leg 230. That is, crystals of the thermoelectric leg 240 are formed in a uniform direction, and crystals of the P-type thermoelectric leg 230 are formed in various directions in comparison with the crystals of the N-type thermoelectric leg 240. To this end, the N-type thermoelectric leg 240 is manufactured through the zone melting method and may have electrical conductivity (S/m) of 100,000 to 110,000, a Seeback coefficient (uV/K) of 200±10, and heat conductivity (W/mK) of 1.2 to 1.6. Further, the P-type thermoelectric leg 230 may be manufactured through the powder sintering method and may have an electrical conductivity (S/m) of 90,000 to 100,000, a Seeback coefficient (uV/K) of 200±10, and a heat conductivity (W/mK) of 0.9 to 1.1. Thus, the heat conductivity and the electrical conductivity are optimized, and thus the thermoelectric performance and the cooling performance of the thermoelectric element including the P-type thermoelectric leg 230 and the N-type thermoelectric leg 240 may be improved.

In this case, X-ray diffraction (XRD) analysis results of the P-type thermoelectric leg 230 and the N-type thermoelectric leg 240 are different.

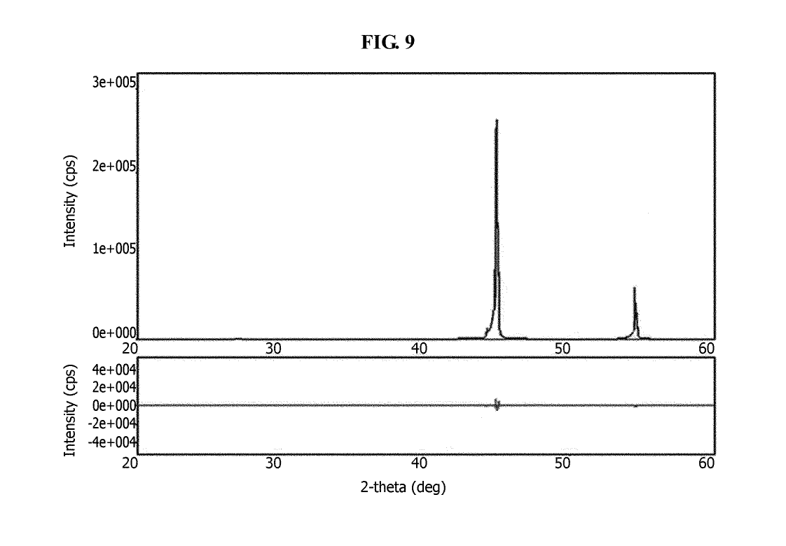

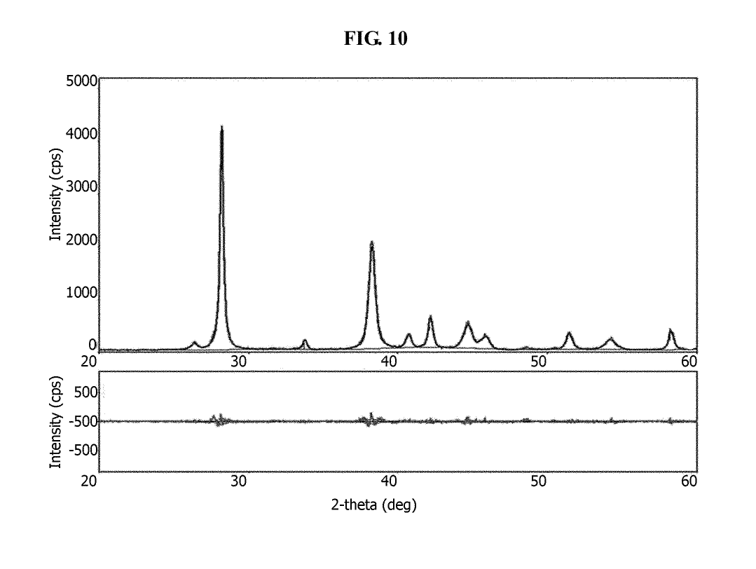

FIG. 9 shows an X-ray diffraction (XRD) analysis result of the N-type thermoelectric leg according to the embodiment of the present invention, and FIG. 10 shows an XRD analysis result of the P-type thermoelectric leg according to the embodiment of the present invention.

Table 2 shows analysis result values of a graph shown in FIG. 9, and Table 3 shows analysis result values of a graph shown in FIG. 10.

TABLE 2

| 2-theta | | Height | Int. I | | FWHM | |
|---|---|---|---|---|---|---|
| (deg) | d(A) | (cps) | (cps deg) | Int. % | (deg) | Phase name |
| 27.903 | 3.1948 | 299 | 157 | 0.47 | 0.29 | Bismuth Antimony Tellurium Selenide, (0, 1, 5) |
| 44.8571 | 2.01892 | 242845 | 32711 | 97.51 | 0.1034 | Bismuth Antimony Tellurium Selenide, (0, 0, 15) |
| 54.235 | 1.6899 | 2548 | 679 | 2.02 | 0.20 | Bismuth Antimony Tellurium Selenide, (0, 0, 18) |

TABLE 3

| 2-theta | | Height | Int. I | | FWHM | |
|---|---|---|---|---|---|---|
| (deg) | d (A) | (cps) | (cps deg) | Int. % | (deg) | Phase name |
| 26.441 | 3.368 | 79 | 46 | 1.45 | 0.43 | Bismuth Antimony Telluride, (0, 0, 9) |
| 28.193 | 3.1627 | 3058 | 1167 | 36.90 | 0.234 | Bismuth Antimony Telluride, (0, 1, 5) |
| 33.72 | 2.6557 | 133 | 59.4 | 1.88 | 0.31 | Bismuth Antimony Telluride, (0, 1, 8) |
| 38.254 | 2.3508 | 1324 | 914 | 28.90 | 0.517 | Bismuth Antimony Telluride, (1, 0, 10) |
| 40.68 | 2.2159 | 160 | 69 | 2.18 | 0.396 | Bismuth Antimony Telluride, (0, 1, 11) |
| 42.121 | 2.1435 | 402 | 183 | 5.79 | 0.352 | Bismuth Antimony Telluride, (1, 1, 0) |
| 44.692 | 2.0260 | 294 | 216 | 6.83 | 0.667 | Bismuth Antimony Telluride, (0, 0, 15) |
| 45.89 | 1.9760 | 149 | 129 | 4.08 | 0.79 | Bismuth Antimony Telluride, (1, 0, 13) |
| 51.379 | 1.7769 | 215 | 128 | 4.05 | 0.449 | Bismuth Antimony Telluride, (2, 0, 5) |
| 54.15 | 1.6925 | 121 | 117 | 3.70 | 0.88 | Bismuth Antimony Telluride, (0, 2, 7) |
| 58.195 | 1.5840 | 286 | 134 | 4.24 | 0.325 | Bismuth Antimony Telluride, (0, 2, 10) |

Referring to FIGS. 9 and 10 and Tables 2 and 3, the number of peaks of the N-type thermoelectric legs 240 is different from the number of peaks of the P-type thermoelectric legs 250 in the XRD analysis within a range of 2θ=20 to 60°, and the number of efficient peaks of the N-type thermoelectric legs 240 is less than the number of efficient peaks of the P-type thermoelectric legs 230. In this case, the efficient peak means a peak including greater than or equal to 4% of the whole peak intensity.

Referring to Table 2, one efficient peak is observed when 2θ=44.8571 as a result of the XRD analysis result when 2θ=20 to 60° for the N-type thermoelectric leg 240 according to the embodiment of the present invention. On the contrary, according to Table 3, seven efficient peaks are observed as a result of the XRD analysis result within the range of 2θ=20 to 60° for the P-type thermoelectric leg 230 according to the embodiment of the present invention. Thus, a result of the XRD analysis within the range of 20=20 to 60° shows that a different between the number of the efficient peaks of the N-type thermoelectric legs 240 and the number of the efficient peaks of the P-type thermoelectric legs 230 is greater than or equal to 6.

Further, the highest peak of the efficient peaks of the N-type thermoelectric legs 240 is shown when 2θ=44.8571, and an intensity of the highest peak is 32711 cps deg and accounts for 97.51% of the total intensity. Thus, the highest peak of the efficient peaks of the P-type thermoelectric leg 230 is shown when 2θ=28.193, and an intensity of the highest peak is 1167 cps deg and accounts for 36.90% of the total intensity. Thus, it was shown that the highest peak intensity of the efficient peaks of the N-type thermoelectric leg 240 was higher than the highest peak intensity of the efficient peaks of the P-type thermoelectric leg 230, and a difference between the highest peak intensity of the efficient peaks of the N-type thermoelectric leg 240 and the highest peak intensity of the efficient peaks of the P-type thermoelectric leg 230 was greater than or equal to 50%.

Meanwhile, the N-type thermoelectric leg 240 is manufactured through the zone melting method, and thus crystals thereof may be formed in a uniform direction. Thus, the highest peak of the efficient peaks of the N-type thermoelectric leg 240 is shown on a (0, 0, X) surface, and X may be a random number. As shown in FIGS. 9 and 10 and Tables 2 and 3, when the N-type thermoelectric leg 240 and the P-type thermoelectric leg 230 include bismuth-telluride (Bi—Te), the N-type thermoelectric leg 240 has the highest peak on the (0, 0, 15) surface, and the P-type thermoelectric leg 230 has the highest peak on the (0, 1, 5) surface as a main peak. Thus, the crystals of the N-type thermoelectric leg 240 are formed in the uniform direction, and the crystals of the P-type thermoelectric leg 230 are formed in various directions in comparison with the crystals of the N-type thermoelectric leg 240.

When the crystal orientations of the N-type thermoelectric leg 240 and the P-type thermoelectric leg 230 are different, a Seeback index may be increased, and cooling performance of the thermoelectric element may be increased.

Table 4 shows results of a comparison between performances in accordance with comparative examples and an example according to the embodiment.

TABLE 4

| | Comparative Example 1 | Comparative Example 2 | Example |
|---|---|---|---|
| Qc(W) | 55.632 | 48.956 | 63.42 |
| ΔT( ) | 66.77 | 58.76 | 76.12 |
| COPc | 0.683 | 0.60 | 0.77 |

In Table 4, Comparative Example 1 is the case in which the N-type thermoelectric leg and the P-type thermoelectric leg have the crystal orientations in FIGS. 3 and 4, respectively, Comparative Example 2 is the case in which an N-type thermoelectric leg and a P-type thermoelectric leg have the crystal orientations in FIGS. 5 and 6, respectively, and Example is the case in which an N-type thermoelectric leg has a crystal orientation in FIG. 3 and a P-type thermoelectric leg has the crystal orientation in FIG. 6.

Qc (W) denotes a cooling thermal capacity, and heat is applied to a cooling unit of a thermoelectric element until a temperature of the cooling unit reaches a temperature of a heat emission unit by reversely using a principle in which a temperature decreases when the thermoelectric element is cooled, and thus the applied heat is measured as Qc (W). A temperature of one surface of the thermoelectric element is uniformly maintained using cooling water, and the thermoelectric element is operated so that the other surface thereof is cooled, and a difference between temperatures of the one surface and the other surface at a point at which the temperature of the other surface does not further decrease any more is measured as ΔT (° C.). COPc is measured by dividing Qc (W) by input power.

Referring to FIG. 4, according to the embodiment of the present invention, when the N-type thermoelectric leg has the crystal orientation in FIG. 3 and the P-type thermoelectric leg has the crystal orientation in FIG. 6, excellent cooling performance may be obtained when comparison with the Comparative Examples 1 and 2.

The thermoelectric element according to the embodiment of the present invention may be applied to a generation device and a heating device in addition to a cooling apparatus. Specifically, the thermoelectric element according to the embodiment of the present invention may be mainly applied to an optical communication module, a sensor, a medical device, a measurement device, the aerospace industry, a refrigerator, a chiller, a vehicle ventilation seat, a cup holder, a washing machine, a dryer, a wine cellar, a purifier, a power supply device for a sensor, a thermopile, and the like.

A polymerase chain reaction (PCR) device may be an example in which the thermoelectric element according to the embodiment of the present invention is applied to a medical device. The PCR device is a device for determining a sequence listing of DNA by amplifying the DNA and is a device in which a precise temperature control is required and a thermal cycle is needed. To this end, a Peltier-based thermoelectric element may be applied to a medical device.

Another example in which the thermoelectric element according to the embodiment of the present invention is applied to a medical device includes an optical detector. In this case, the optical detector may be an infrared-ultraviolet detector, a charge coupled device (CCD) sensor, an x-ray detector, a thermoelectric thermal reference source (TTRS), or the like. A Peltier-based thermoelectric element may be applied to cool the optical detector. Therefore, a wavelength change, output decrease, resolution degradation, and the like due to a temperature increase in the optical detector may be prevented.

Still another example in which the thermoelectric element according to the embodiment of the present invention is applied to a medical device includes the immunoassay analyzer, the in vitro diagnostics device, a general temperature control and cooling system, the physical treatment device, a liquid chiller system, the blood-plasma temperature control device, and the like. Thus, a precise temperature control is possible.

Yet another example in which the thermoelectric element according to the embodiment of the present invention is applied to a medical device includes an artificial heart. Thus, power may be supplied to the artificial heart.

An example in which the thermoelectric element according to the embodiment of the present invention is applied to the aerospace industry includes an astrotracker, a thermal image camera, an infrared-ultraviolet detector, a CCD sensor, a Hubble space telescope, a TTRS, and the like. Thus, a temperature of an image sensor may be maintained.

Another example in which the thermoelectric element according to the embodiment of the present invention is applied to the aerospace industry includes a cooling apparatus, a heater, a generation device, and the like.

While the example embodiments of the present invention and their advantages have been described above in detail, it should be understood that various changes, substitutions and alterations may be made herein without departing from the scope of the invention as defined by the following claims.

### DESCRIPTION OF SYMBOLS

200: THERMOELECTRIC ELEMENT
210: LOWER SUBSTRATE
220: LOWER ELECTRODE
230: P-TYPE THERMOELECTRIC LEG
240: N-TYPE THERMOELECTRIC LEG
250: UPPER ELECTRODE
260: UPPER SUBSTRATE

1. A thermoelectric element comprising:
a first substrate;
a plurality of P-type thermoelectric legs and a plurality of N-type thermoelectric legs alternately disposed on the first substrate;
a second substrate disposed on the plurality of P-type thermoelectric legs and the plurality of N-type thermoelectric legs; and
a plurality of electrodes configured to connect the plurality of P-type thermoelectric legs with the plurality of N-type thermoelectric legs in series,
wherein the number of peaks of the N-type thermoelectric legs and the number of peaks of the P-type thermoelectric legs are different in an X-ray diffraction (XRD) analysis within a range of 2θ=20 to 60°.

2. The thermoelectric element of claim 1, wherein:
the number of efficient peaks of the N-type thermoelectric legs is less than the number of efficient peaks of the P-type thermoelectric legs; and
the efficient peaks account for 4% or more of 100% total peak intensity.

3. The thermoelectric element of claim 2, wherein a difference between the number of efficient peaks of the N-type thermoelectric legs and the number of efficient peaks of the P-type thermoelectric legs is 6 or more.

4. The thermoelectric element of claim 2, wherein a highest peak intensity of the effective peaks of the N-type thermoelectric legs is greater than a highest peak intensity of the effective peaks of the P-type thermoelectric legs.

5. The thermoelectric element of claim 4, wherein a difference between the highest peak intensity of the efficient peaks of the N-type thermoelectric legs and the highest peak intensity of the efficient peaks of the P-type thermoelectric legs is 50% or more.

6. The thermoelectric element of claim 2, wherein a highest peak of the efficient peaks of the N-type thermoelectric legs is shown on a (0, 0, X) surface,
wherein X is a random number.

7. The thermoelectric element of claim 2, wherein a highest peak intensity of the efficient peaks of the N-type thermoelectric legs is 90% or more of 100% total intensity.

8. The thermoelectric element of claim 2, wherein the N-type thermoelectric legs and the P-type thermoelectric legs include bismuth-telluride (Bi—Te).

9. The thermoelectric element of claim 8, wherein:
the N-type thermoelectric legs have the highest peak on a (0, 0, 15) surface; and
the P-type thermoelectric legs have the highest peak on the a (0, 1, 5) surface.

10. The thermoelectric element of claim 2, wherein the N-type thermoelectric legs may have more uniform crystal orientations than the crystal orientations of the P-type thermoelectric legs.

11. The thermoelectric element of claim 2, wherein the N-type thermoelectric leg has heat conductivity greater than that of the P-type thermoelectric leg.

12. The thermoelectric element of claim 2, wherein:
the N-type thermoelectric legs are manufactured through a zone-melting method; and
the P-type thermoelectric legs are manufactured through a powder sintering method.

13. The thermoelectric element of claim 2, wherein the number of the efficient peaks of the N-type thermoelectric legs is 1.

14. The thermoelectric element of claim 1, wherein:
the N-type thermoelectric leg has electrical conductivity (S/m) of 100,000 to 110,000, a Seeback index (uV/K) of 200±10, and heat conductivity (W/mK) of 1.2 to 1.6; and
the P-type thermoelectric leg has electrical conductivity (S/m) of 90,000 to 100,000, a Seeback index (uV/K) of 200±10, and heat conductivity (W/mK) of 0.9 to 1.1.

15. A cooling apparatus comprising a thermoelectric element, the cooling apparatus comprising:
a first substrate;
a plurality of P-type thermoelectric legs and a plurality of N-type thermoelectric legs alternately disposed on the first substrate;
a second substrate disposed on the plurality of P-type thermoelectric legs and the plurality of N-type thermoelectric legs; and
a plurality of electrodes configured to connect the plurality of P-type thermoelectric legs with the plurality of N-type thermoelectric legs in series,
wherein the number of peaks of the N-type thermoelectric legs and the number of peaks of the P-type thermoelectric legs are different in an X-ray diffraction (XRD) analysis within a range of 2θ=20 to 60°.

16. The cooling apparatus of claim 15, wherein:
the number of efficient peaks of the N-type thermoelectric legs is less than the number of efficient peaks of the P-type thermoelectric legs; and
the efficient peaks account for 4% or more of 100% total peak intensity.

17. The cooling apparatus of claim 16, wherein a highest peak intensity of the efficient peaks of the N-type thermoelectric legs is greater than a highest peak intensity of the efficient peaks of the P-type thermoelectric legs.

18. The cooling apparatus of claim 16, wherein crystal orientations of the N-type thermoelectric legs are more uniform than crystal orientations of the P-type thermoelectric legs.

19. The cooling apparatus of claim 16, wherein:
the N-type thermoelectric legs are manufactured through a zone-melting method; and
the P-type thermoelectric legs are manufactured through a powder sintering method.

20. The cooling apparatus of claim 16, wherein the number of the efficient peaks of the N-type thermoelectric legs is 1.
